(19) United States
(12) Patent Application Publication
(10) Pub. No.: US 2026/0143598 A1
(43) Pub. Date: May 21, 2026

(54) ENERGY STORAGE SYSTEM

(71) Applicant: ZHEJIANG JINKO ENERGY STORAGE CO., LTD., Haining City (CN)

(72) Inventors: Jian YU, Haining City (CN); Xuebing SUN, Haining City (CN); Luhua ZHANG, Haining City (CN); Guodong XU, Haining City (CN)

(73) Assignee: ZHEJIANG JINKO ENERGY STORAGE CO., LTD., Haining City (CN)

(21) Appl. No.: 19/361,232

(22) Filed: Oct. 17, 2025

(30) Foreign Application Priority Data
Nov. 18, 2024 (CN) 202411650741.4

(51) Int. Cl. H05K 5/02; H01H 71/02; H01M 50/251

(52) U.S. Cl. CPC H05K 5/0204; H01H 71/0214; H01H 71/0221; H01H 71/0235; H01M 50/251; H05K 5/0247; H01H 2071/0242

(57) ABSTRACT

Provided is an energy storage system, including: an energy storage cabinet, a high-voltage box and power conversion systems that are located in the energy storage cabinet, the power conversion systems are electrically connected to the high-voltage box. The high-voltage box includes a box body with accommodating cavity, circuit breakers electrically connected to electronic components through connecting members, and a first mounting bracket for installing the circuit breakers. The first mounting bracket includes first and second main body portions connected to each other. The first main body portion is installed within the accommodating cavity. Along height direction of the high-voltage box, the circuit breakers are sequentially installed to the second main body portion. The electronic components are located on a side of the second main body portion away from the circuit breakers. The high-voltage box further includes support members connected to the connecting members and the first mounting bracket.

### CROSS-REFERENCE TO RELATED APPLICATION(S)

The present application claims priority to Chinese Patent Application No. 202411650741.4, filed on November 18, 2024, the content of which is incorporated herein by reference in its entirety.

### TECHNICAL FIELD

The present disclosure relates to the field of energy storage, and particularly to an energy storage system.

### BACKGROUND

With the development of technologies, the application of photovoltaic energy storage has become increasingly widespread. An energy storage system includes a container, a high-voltage box, and a power conversion system. Typically, the high-voltage box is installed inside the container, while the power conversion system is placed outside the container. As a result, the high-voltage box occupies a relatively large space.

### SUMMARY

In view of this, an energy storage system is proposed for reducing the volume of the high-voltage box.

Embodiments of the present disclosure provide an energy storage system, including an energy storage cabinet, a high-voltage box, and at least two power conversion systems. The high-voltage box and the power conversion systems are located within the energy storage cabinet, and the at least two power conversion systems are electrically connected to the high-voltage box. The high-voltage box includes: a box body provided with an accommodating cavity; electronic components located within the accommodating cavity; at least two circuit breakers electrically connected to the electronic components through connecting members; a first mounting bracket configured to install the at least two circuit breakers to the box body. The first mounting bracket includes a first main body portion and a second main body portion that are connected to each other, and the first main body portion is detachably installed within the accommodating cavity. Along a height direction of the high-voltage box, each of the at least two circuit breakers is sequentially installed to the second main body portion, and the at least two circuit breakers can be installed to or removed from the high-voltage box together with the first mounting bracket. The electronic components are located on a side of the second main body portion away from the at least two circuit breakers. The high-voltage box further includes at least one support member, one end of the support member is connected to the connecting members, and the other end is connected to the first mounting bracket.

In one or more embodiments, the box body is provided with a snap-fit portion, and the first mounting bracket is provided with a first mating portion. The snap-fit portion is provided on a bottom wall of the accommodating cavity and protrudes in a direction away from the bottom wall. The included angle between the snap-fit portion and the bottom wall is an acute angle, the space between the snap-fit portion and the bottom wall is a snap-fit space, and at least part of the first mating portion can extend into the snap-fit space. The first mating portion is provided with at least one mating groove, and when the snap-fit portion cooperates with the first mating portion, at least part of the snap-fit portion is located within the mating groove. The cooperation between the snap-fit portion and the first mating portion is configured to limit the relative position of the first mounting bracket and the box body.

In one or more embodiments, the first main body portion is provided with at least one second mating portion, the second mating portion is connected to the high-voltage box through mounting members, and along a length direction of the first main body portion, the first mating portion and the second mating portion are located at opposite ends of the first main body portion.

In one or more embodiments, the at least one support member is connected to a side of the second main body portion away from the at least two circuit breakers; and/or, the first mounting bracket is provided with a flanging, the flanging forms an included angle between and the first main body portion and/or the second main body portion, and the at least one support member is connected to the flanging.

In one or more embodiments, the first mounting bracket further includes a third main body portion, the third main body portion is located on a side of the second main body portion away from the first main body portion, one end of the third main body portion is connected to the second main body portion, and the other end is connected to the box body.

In one or more embodiments, the high-voltage box further includes a first insulating member, the first insulating member includes a first body part, a second body part, and a third body part, and the first body part and the third body part are located at opposite sides of the second body part and each forms an included angle with the second body part. The first body part, the second body part, and the third body part enclose to form an accommodating space, and the at least two circuit breakers are located within the accommodating space.

In one or more embodiments, each of the connecting members includes a first connecting section, a second connecting section, and at least one transition section, and the first connecting section and the second connecting section are connected through the transition section. The transition section forms an included angle with the first connecting section and/or the second connecting section. The first connecting section is electrically connected to the circuit breaker, and the second connecting section is electrically connected to the electronic components. The connecting members can be installed to or removed from the high-voltage box together with the at least two circuit breakers.

In one or more embodiments, the high-voltage box includes an arc-extinguisher and a second insulating member, the arc-extinguisher is located at an input end of the circuit breaker, and the second insulating member is located at an output end of the circuit breaker. The connecting members includes a first connecting member and a second connecting member, the electronic components include a fuse and a relay, one end of the first connecting member is electrically connected to a positive terminal of the output end of the circuit breaker, and the other end is electrically connected to the fuse, one end of the second connecting member is electrically connected to a negative terminal of the output end of the circuit breaker, and the other end is electrically connected to the relay. At least part of the second insulating member is located between the first connecting member and the second connecting member.

In one or more embodiments, the high-voltage box includes a second mounting bracket, and the second mounting bracket is located within the accommodating cavity. The second mounting bracket includes a mounting portion and a supporting portion, a gap between the supporting portion and a bottom wall of the accommodating cavity, and the supporting portion is connected to the box body. One of the fuse and the relay is located on a side of the mounting portion away from the bottom wall of the accommodating cavity, and the other is located on a side of the mounting portion close to the bottom wall of the accommodating cavity.

In one or more embodiments, the circuit breaker is provided with a mounting groove, and the arc-extinguisher is provided with a third mating portion. At least part of the third mating portion can extend into the mounting groove. The high-voltage box further includes a stop block, the stop block is connected to the second main body portion, and the stop block is located on a side of the arc-extinguisher away from the circuit breaker and is configured to limit the movement of the arc-extinguisher relative to the circuit breaker.

Embodiments of the present disclosure provide an energy storage system. The energy storage system includes an energy storage cabinet, a high-voltage box, and at least two power conversion systems. The high-voltage box and the power conversion systems are located in the energy storage cabinet, and the power conversion systems are electrically connected to the high-voltage box. The high-voltage box includes a box body with an accommodating cavity, at least two circuit breakers electrically connected to electronic components through connecting members, and a first mounting bracket for mounting the circuit breakers. The first mounting bracket includes a first main body portion and a second main body portion that are connected to each other. The first main body portion is detachably installed within the accommodating cavity. Along the height direction of the high-voltage box, each of the at least two circuit breakers is sequentially installed to the second main body portion. The at least two circuit breakers can be installed to or removed from the high-voltage box together with the first mounting bracket. The electronic components are located on the side of the second main body portion away from the at least two circuit breakers. The high-voltage box further includes at least one support member, one end of the support member is connected to the connecting members, and the other end is connected to the first mounting bracket. Such a design is beneficial for reducing the volume of the high-voltage box, lowering the assembly difficulty, and improving the production efficiency.

It should be understood that the above general description and the following detailed description are merely exemplary and do not limit the scope of the present disclosure.

### BRIEF DESCRIPTION OF DRAWINGS

To more clearly illustrate the technical solutions of the embodiments of the present disclosure, the accompanying drawings used in the embodiments will be briefly introduced. It is appreciated that, the accompanying drawings in the following description are only some embodiments of the present disclosure. For those of ordinary skill in the art, other drawings can also be obtained from these drawings without any creative effort.

FIG. 1 is a schematic diagram of a high-voltage box according to one or more embodiments of the present disclosure.

FIG. 2 is an internal schematic diagram of a high-voltage box according to one or more embodiments of the present disclosure.

FIG. 3 is a schematic diagram of a first mounting bracket according to one or more embodiments of the present disclosure.

FIG. 4 is a schematic diagram of a box body according to one or more embodiments of the present disclosure.

FIG. 5 is a partial enlarged view of position I in FIG. 4.

FIG. 6 is a schematic diagram of a circuit breaker and a mounting bracket according to one or more embodiments of the present disclosure.

FIG. 7 is a schematic diagram of a mounting module according to one or more embodiments of the present disclosure.

FIG. 8 is a schematic diagram of a first mounting bracket according to one or more embodiments of the present disclosure.

FIG. 9 is a cross-sectional view of a high-voltage box according to one or more embodiments of the present disclosure.

FIG. 10 is a schematic diagram of a circuit breaker according to one or more embodiments of the present disclosure.

FIG. 11 is a schematic diagram of an arc-extinguisher according to one or more embodiments of the present disclosure.

FIG. 12 is a schematic diagram of an energy storage system according to one or more embodiments of the present disclosure.

### DESCRIPTION OF EMBODIMENTS

To better understand the technical solutions of the present disclosure, embodiments of the present disclosure will be described in detail below with reference to the accompanying drawings.

It should be clear that the described embodiments are only some of the embodiments of the present disclosure, not all of the embodiments.

The terms used in the embodiments of the present disclosure are only for the purpose of describing specific embodiments and are not intended to limit the present disclosure. The singular forms “a/an”, “the” and “said” used in the embodiments of the present disclosure and the appended claims are also intended to include plural forms, unless the context clearly indicates otherwise.

It should be understood that the term “and/or” used herein is only an associated relationship describing associated objects, indicating that there can be three relationships. For example, A and/or B refers to: A exists alone, both A and B exist simultaneously, and B exists alone. In addition, the character “/” herein generally indicates an “or” relationship between the associated objects.

Photovoltaic energy storage can convert solar energy into electrical energy for storage. The energy storage container is one of the important devices for photovoltaic energy storage, and its function is to store the electrical energy collected by the photovoltaic panels. The energy storage container is usually equipped with a power conversion system (PCS) 30 and a high-voltage box 20. The power conversion system 30 is a device for storing electrical energy and can convert direct current into alternating current, thereby providing electrical energy for external devices. The high-voltage box 20 is used to control the connection or disconnection of the main electrical circuit of the system to ensure the safe operation of the battery energy storage system.

Generally, the high-voltage box 20, as an independent cabinet, is placed separately inside the container. With the development of technologies, integrating the power conversion system 30 inside the container has become a trend. Due to the limited space inside the container, integrating the power conversion system 30 inside the container will compress the assembly space of the high-voltage box 20. Therefore, new requirements are put forward for the structure of the high-voltage box 20.

Embodiments of the present disclosure provide an energy storage system. The energy storage system may include an energy storage cabinet 10, a high-voltage box 20, and a power conversion system 30. The high-voltage box 20 and the power conversion system 30 are installed in the energy storage cabinet 10.

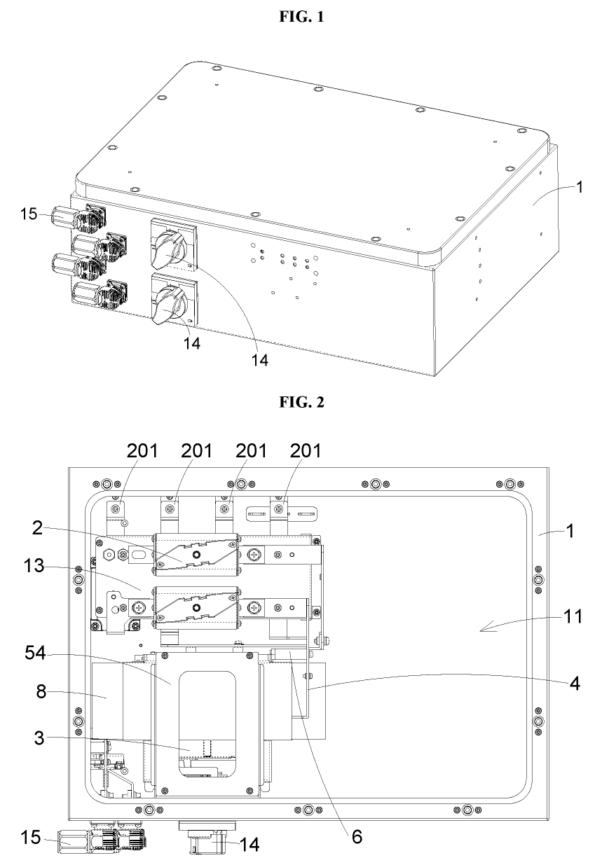

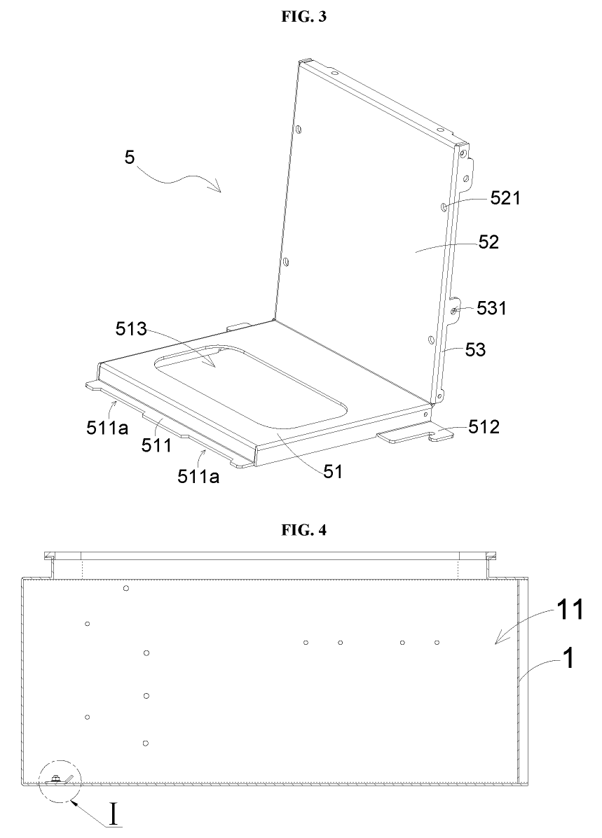

As shown in FIG. 1 and FIG. 2, embodiments of the present disclosure provide a high-voltage box 20. The high-voltage box 20 includes a box body 1, electronic components 2, a first mounting bracket 5, and at least two circuit breakers 3. The box body 1 is provided with an accommodating cavity 11, which is used to accommodate the first mounting bracket 5, the circuit breakers 3, and the electronic components 2. The circuit breakers 3 are installed to the first mounting bracket 5 and are installed to the high-voltage box 20 together with the first mounting bracket 5, or removed from the high-voltage box 20 together with the first mounting bracket 5. The circuit breakers 3 are electrically connected to the electronic components 2 through connecting members 4 and are used to control the connection or disconnection of the overall circuit of the energy storage system. As shown in FIG. 3, the first mounting bracket 5 includes a first main body portion 51 and a second main body portion 52. The first main body portion 51 and the second main body portion 52 are connected to each other and form an included angle therebetween. The first main body portion 51 and the second main body portion 52 can be arranged in an "L" shape. The first main body portion 51 is connected to the box body 1, and the circuit breakers 3 are installed to the first mounting bracket 5 through the second main body portion 52.

When assembling the high-voltage box 20, the circuit breakers 3 can be installed to the first mounting bracket 5 outside the high-voltage box 20 first, so that the circuit breakers 3 and the first mounting bracket 5 form a mounting module, and then the circuit breakers 3 and the first mounting bracket 5 are installed as a whole inside the high-voltage box 20.

When the volume of the high-voltage box 20 decreases, the internal space of the high-voltage box 20 will decrease accordingly. When directly installing the circuit breakers 3 inside the high-voltage box 20, due to the limited space, the installation operation is more difficult, resulting in a decrease in assembly efficiency. Compared with the scheme of directly installing the circuit breakers 3 within the box body 1 of the high-voltage box 20, installing the circuit breakers 3 outside the high-voltage box 20 can help increase the operating space and facilitate the operation of the operator.

The high-voltage box 20 provided by embodiments of the present disclosure includes at least two circuit breakers 3. Each circuit breaker 3 is used to control one power conversion system 30, and each circuit breaker 3 is sequentially installed to the second main body portion 52 of the first mounting bracket 5 along the thickness direction of the high-voltage box 20.

In the solutions provided by embodiments of the present disclosure, by arranging the circuit breakers 3 in sequence along the height direction of the high-voltage box 20, the space utilization rate of the high-voltage box 20 in the height direction can be improved, thereby improving the integration degree of the high-voltage box 20, making the overall structure of the high-voltage box 20 more compact, and thus helping to reduce the overall volume of the high-voltage box 20. Since the volume of the high-voltage box 20 is reduced, the internal space of the high-voltage box 20 is limited, and the operating space left for the operator when installing the circuit breakers 3 is small. When installing multiple circuit breakers 3, due to insufficient operating space, the installation is more difficult or even impossible. By adopting the solutions provided by embodiments of the present disclosure, each circuit breaker 3 can be installed to the first mounting bracket 5 outside the high-voltage box 20 in advance, so that there is enough space to install the circuit breakers 3 for the operator, reducing the operating difficulty. After the installation of the circuit breakers 3 and the first mounting bracket 5 is completed, the circuit breakers 3 and the first mounting bracket 5 are installed as a whole inside the high-voltage box 20. By modularizing the circuit breakers 3 and the first mounting bracket 5, the space utilization rate of the high-voltage box 20 can be improved, and the installation difficulty can be reduced.

As shown in FIG. 2, in one or more embodiments, one end of the connecting member 4 is connected to the circuit breaker 3, and the other end is connected to the electronic components 2. The high-voltage box 20 further includes at least one support member 6. One end of the support member 6 is connected to the connecting member 4, and the other end is connected to the first mounting bracket 5.

By providing the support member 6, the connecting member 4 can be supported, thus reducing the possibility of deformation of the connecting member 4 during use.

As shown in FIG. 3, FIG. 4, and FIG. 5, in one or more embodiments, the box body 1 is provided with a snap-fit portion 12, and the first mounting bracket 5 is provided with a first mating portion 511. The snap-fit portion 12 is used to cooperate with the first mating portion 511 to limit the relative position between the first mounting bracket 5 and the box body 1.

Connecting the first mounting bracket 5 and the box body 1 by means of snap-fit connection can help reduce the operation difficulty, thereby reducing the demand for operating space. Moreover, the snap-fit connection is also convenient for disassembly. When it is necessary to remove the circuit breakers 3 from the high-voltage box 20, it is only necessary to release the snap-fit connection between the first mounting bracket 5 and the box body 1, and the operation is relatively convenient and fast.

As shown in FIG. 5, in one or more embodiments, the snap-fit portion 12 is arranged on the bottom wall of the accommodating cavity 11 and protrudes in a direction away from the bottom wall. There is an included angle between the snap-fit portion 12 and the bottom wall, and the included angle is embodied as an acute angle. The space between the snap-fit portion 12 and the bottom wall of the accommodating cavity 11 can be used to form snap-fit space, and at least part of the first mating portion 511 can extend into the snap-fit space for snap-fit connection.

Such a design can facilitate the connection between the first mounting bracket 5 and the box body 1. When the first mating portion extends into the snap-fit space, it enables the snap-fit portion 12 to achieve limitation on the first mating portion 511, and then the position of the first mounting bracket 5 can be limited, which is beneficial to improving the installation position accuracy of the first mounting bracket 5 and better meets the actual use requirements.

As shown in FIG. 3, in one or more embodiments, the first mating portion 511 is provided with at least one mating groove 511a. When the snap-fit portion 12 cooperates with the first mating portion 511, at least part of the snap-fit portion 12 is located within the mating groove 511a.

By providing the mating groove 511a, snap-fit connection can be formed through the cooperation between the snap-fit portion 12 and the mating groove 511a, which can further improve the connection stability between the snap-fit portion 12 and the first mounting bracket 5. By making the first mating portion 511 extend into the snap-fit space, the first mounting bracket 5 can be limited in the height direction of the high-voltage box 20. The manner of extending the snap-fit portion 12 into the mating groove 511a can be used to limit the shaking between the snap-fit portion 12 and the first mounting bracket 5, which is beneficial to improving the connection stability between the circuit breaker 3, the first mounting bracket 5 and the high-voltage box 20, and reducing the possibility that the circuit breaker 3 deviates from the preset position due to shaking during transportation and use, which may result in malfunction of the high-voltage box 20.

As shown in FIG. 5, in one or more embodiments, the snap-fit portion 12 is fixedly connected to the box body 1.

The snap-fit portion 12 can be a component independent of the box body 1 and is fixedly installed to the box body 1 by means of welding, bonding, threaded connection, etc. This design can adjust the position and quantity of the snap-fit portion 12 according to actual use requirements, making the configuration of the high-voltage box 20 more flexible and beneficial to improving the space utilization rate of the high-voltage box 20.

In one or more embodiments, the snap-fit portion 12 can be integrally formed with the box body 1.

By adopting the integral-forming manner, the assembling steps of the high-voltage box 20 can be reduced. The snap-fit portion 12 formed integrally has better integrity, and is suitable for mass production. Moreover, since the standardized design of the high-voltage box 20 is achieved, the versatility of the high-voltage box 20 is improved.

As shown in FIG. 3, in one or more embodiments, the first main body portion 51 is provided with at least one second mating portion 512. The second mating portion 512 can be connected to the high-voltage box 20 through mounting members such as screws and bolts. Along the length direction of the first main body portion 51, the first mating portion 511 and the second mating portion 512 are located at opposite ends of the first main body portion 51.

By providing the second mating portion 512, the contact area between the first mounting bracket 5 and the box body 1 can be increased, thereby improving the connection stability. The first mating portion 511 and the second mating portion 512 are on different sides of the first main body portion 51. During installation, the first mounting bracket 5 and the box body 1 can be connected in different positions, thus enhancing the installation stability of the first mounting bracket 5 and reducing the possibility of the first mounting bracket 5 shaking during transportation and use.

As shown in FIG. 3, in one or more embodiments, the first main body portion 51 is provided with a through-hole 513, and the through-hole 513 penetrates through the first main body portion 51 along the thickness direction of the high-voltage box 20.

By providing the through-hole 513 on the first main body portion 51, it can be used to receive wire harnesses. During the assembly process, the wire harnesses can pass through the through-hole 513. In addition, the through-hole 513 also has the function of weight reduction, which is beneficial for reducing the weight of the first mounting bracket 5 and thus reducing the overall weight of the high-voltage box 20.

As shown in FIG. 3, in one or more embodiments, the second main body portion 52 is provided with a first mounting hole 521, and the circuit breaker 3 is installed to the first mounting bracket 5 through the first mounting hole 521.

By providing the first mounting hole 521, it is convenient for the connection of the circuit breaker 3 and the first mounting bracket 5.

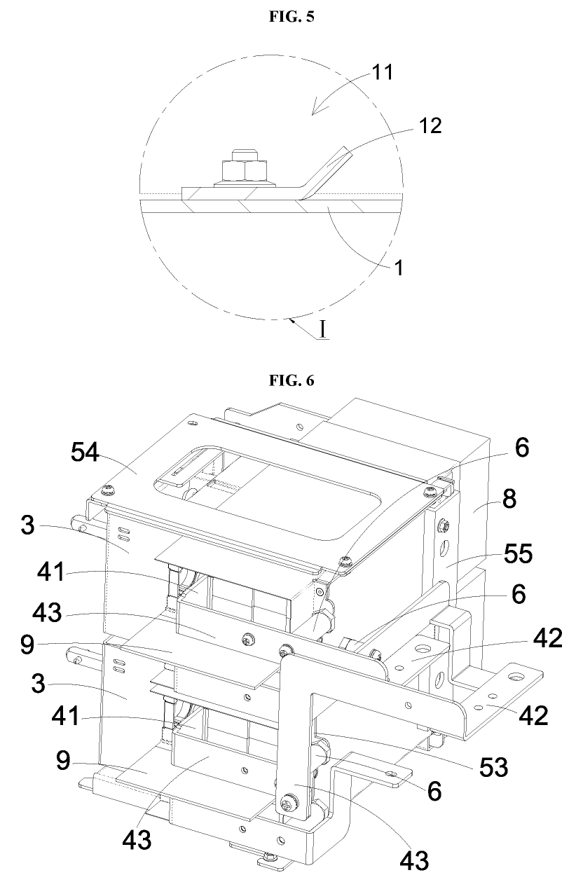

As shown in FIG. 6, in one or more embodiments, at least one support member 6 is connected to the side of the second main body portion 52 away from the circuit breaker 3.

One end of the support member 6 is connected to the connecting member 4, and the other end is connected to the first mounting bracket 5. Through this design, the connecting member 4 can be well supported.

In the scheme of directly installing the circuit breaker 3 within the high-voltage box 20 in the related art, since the first mounting bracket 5 is not provided, when the size of the connecting member 4 is large and the connecting member 4 needs to be supported, the connecting member 4 can only be arranged along the inner wall of the high-voltage box 20, and a support structure is provided on the inner wall of the high-voltage box 20. In this way, the connecting member 4 generally has a straight-line structure. Therefore, the relative position of the circuit breakers 3 and the electronic components 2 electrically connected to the circuit breakers 3 may be affected by the support structure. The electronic components 2 can only be located on the side where the output end of the circuit breaker 3 is provided, resulting in limitations on the overall layout of the high-voltage box 20. It is not conducive to the optimal design of the internal structure of the high-voltage box 20, leading to an increase in the volume of the high-voltage box 20. Moreover, since the support member 6 is provided on the inner wall of the box body 1, during installation, operations need to be carried out inside the box body 1. However, the space inside the box body 1 is limited, resulting in increased connection difficulty and affecting the assembly efficiency.

In the solutions provided by embodiments of the present disclosure, by providing the first mounting bracket 5, the support member 6 can be provided on the first mounting bracket 5. Therefore, the position of the electronic components 2 can be adjusted according to the layout requirements of the high-voltage box 20. The connecting member 4 can be set as an irregular-shaped connecting member 4. That is, the connecting member 4 is not necessarily in a straight-line structure. The connecting member 4 can include one or more bent sections, and the connecting member 4 is supported by the support member 6. Thus, the electronic components 2 can be arranged on the side of the second main body portion 52 away from the circuit breakers 3. In other words, the electronic components 2 is not limited to the side where the output end of the circuit breaker 3 is.

Furthermore, during the process of assembling the high-voltage box 20, the connecting member 4 can be electrically connected to the circuit breakers 3 in advance and connected to the support member 6. This way only requires connecting the connecting member 4 and the electronic components 2 within the high-voltage box 20, which can reduce the operation steps to be performed inside the high-voltage box 20, and thus is beneficial to reducing the assembly difficulty and improving the assembly efficiency.

As shown in FIG. 6, in one or more embodiments, the first mounting bracket 5 is provided with a flanging 53. the flanging 53 forms an included angle with the first main body portion 51 and/or the second main body portion 52. At least one support member 6 is connected to the flanging 53.

Providing the flanging 53 can strengthen the first main body portion 51 and the second main body portion 52, thus improving the structural strength of the first mounting bracket 5, which better meets the actual use requirements. Moreover, by providing the flanging 53, the area of the first mounting bracket 5 can be increased. The support member 6 can be connected to the flanging 53, thereby enhancing the flexibility of arranging the support member 6, and in turn, improving the flexibility of arranging the connecting member 4. The support member 6 can be connected to one or more of the box body 1, the second main body portion 52, and the flanging 53 according to actual needs, which is beneficial for optimizing the internal structure of the high-voltage box 20 and thus reducing the volume of the high-voltage box 20.

In one or more embodiments, the support member 6 can be installed to the first mounting bracket 5 by means of welding, bonding, threaded connection, etc. The side of the second main body portion 52 away from the circuit breakers 3 may be provided with a second mounting hole and/or the flanging 53 is provided with a third mounting hole 531. Installing the support member 6 through the mounting hole can improve the positioning accuracy of the support member 6 during installation and increase the contact area between the first mounting bracket 5 and the support member 6, thus contributing to enhancing the connection stability of the support member 6, which is more in line with the actual use requirements.

As shown in FIG. 6, in one or more embodiments, the first mounting bracket 5 may also include a third main body portion 54. The third main body portion 54 is located on the side of the second main body portion 52 away from the first main body portion 51. That is, the first main body portion 51 and the third main body portion 54 are located on opposite sides of the second main body portion 52. The first main body portion 51, the second main body portion 52, and the third main body portion 54 can be used to enclose a horizontally-placed U-shaped structure, and the opening of the U-shaped structure faces the side wall of the box body 1. One end of the third main body portion 54 is connected to the second main body portion 52, and the other end is connected to the box body 1.

The third main body portion 54 can be connected to the second main body portion 52 and the box body 1 by means of threaded connection, etc., which is used to increase the contact area and connection points between the first mounting bracket 5 and the box body 1, thus improving the connection stability between the first mounting bracket 5 and the box body 1. Along the thickness direction of the high-voltage box 20, the lower part of the first mounting bracket 5 is connected to the box body 1 through the first mating portion 511 and the second mating portion 512, and the upper part of the first mounting bracket 5 is connected to the box body 1 through the third main body portion 54. This can help reduce the possibility of the first mounting bracket 5 shaking during transportation and use, thus contributing to enhancing the installation stability of the circuit breakers 3, which better meets the actual use requirements.

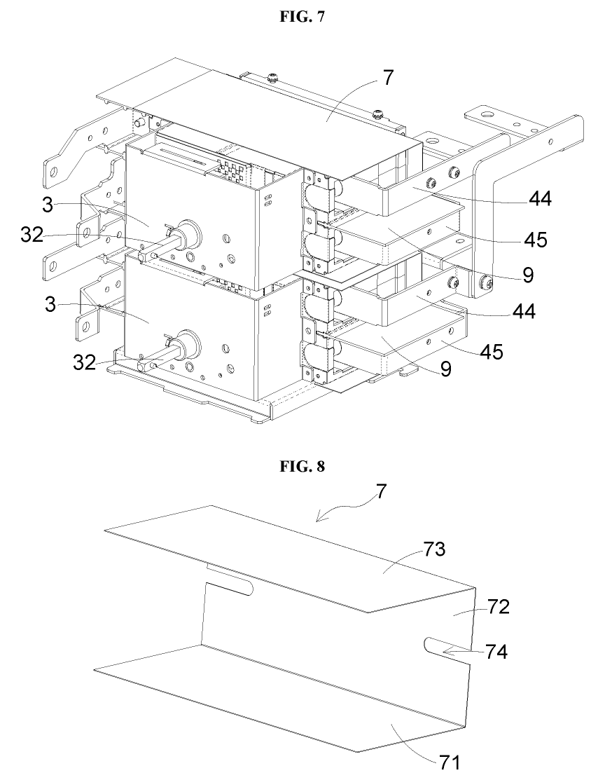

As shown in FIG. 7, in one or more embodiments, the high-voltage box 20 further includes a first insulating member 7. As shown in FIG. 8, the first insulating member 7 includes a first body part 71, a second body part 72, and a third body part 73. The first body part 71 and the third body part 73 are located on opposite sides of the second body part 72 and each form an included angle with the second body part 72. The second body part 72 and the third body part 73 are used to enclose an accommodating space, and the circuit breakers 3 are provided within the corresponding accommodating space.

The first insulating member 7 can be in an approximate U-shaped structure, covering the outside of the circuit breaker 3 for insulation, reducing the possibility of contact between adjacent circuit breakers 3, thereby improving the operational stability and safety of the high-voltage box 20.

As shown in FIG. 8, in one or more embodiments, the first insulating member 7 may also include an avoidance groove 74, which is used to provide room for the connection position between the circuit breaker 3 and the first mounting bracket 5.

The avoidance groove 74 can be provided on the second body part 72. During assembly, along the thickness direction of the high-voltage box 20, the first body part 71 and the third body part 73 are located on opposite sides of the circuit breaker 3, and the second body part 72 is located on the side of the circuit breaker 3 facing the second main body portion 52. By providing the avoidance groove 74, the interference of the first insulating member 7 with the connection position between the circuit breaker 3 and the first mounting bracket 5 can be reduced, thus decreasing the impact of the connecting member 4 on the installation stability of the circuit breaker 3, which better meets the actual use requirements.

In one or more embodiments, the first insulating member 7 can be insulating paper.

Insulating paper has good insulating properties and high strength, and can withstand the pressure of high-voltage electric fields and mechanical stresses, which can ensure the normal operation of the high-voltage box 20. In addition, insulating paper also has good thermal-resistant capabilities. When the high-voltage box 20 is applied outdoors, it can adapt to different environments, which is more in line with the actual use requirements.

As shown in FIG. 6, in one or more embodiments, the connecting member 4 includes a first connecting section 41, a second connecting section 42, and at least one transition section 43. The first connecting section 41 and the second connecting section 42 are connected through the transition section 43, and the transition section 43 forms an included angle with and the first connecting section 41 and/or the second connecting section 42. The first connecting section 41 is electrically connected to the circuit breaker 3, the second connecting section 42 is electrically connected to the electronic components 2, and the connecting member 4 can be installed to or removed from the high-voltage box 20 together with the circuit breaker 3.

The connecting member 4 can have a multi-section structure. The relative position of the first connecting section 41 and the second connecting section 42 are arranged according to the relative position of the circuit breaker 3 and the electronic components 2, and the first connecting section 41 and the second connecting section 42 are connected through the transition section 43, making the relative position between the circuit breaker 3 and the electronic components 2 more flexible. This improves the utilization rate of the internal space of the high-voltage box 20 and helps to reduce the volume of the high-voltage box 20.

In one or more embodiments, the extending directions of the first connecting section 41 and the second connecting section 42 can be parallel, and there can be one or more transition sections 43 between the first connecting section 41 and the second connecting section 42. The connecting member 4 can be integrally formed or formed as a segmented structure connected by mounting members such as screws and bolts or by means of welding, bonding, etc.

When the connecting member 4 is integrally formed, it has better integrity, as well as good strength and precision.

When the connecting member 4 has a segmented structure, the structure of the connecting member 4 is more flexible. Transition sections 43 with different structures can be pre-processed. During assembly, suitable transition sections 43 can be selected for assembly according to actual needs.

As shown in FIG. 6, in one or more embodiments, at least part of the first connecting section 41 is located on the side of the second main body portion 52 close to the circuit breaker 3, and at least part of the second connecting section 42 is located on the side of the second main body portion 52 away from the circuit breaker 3. In the width direction of the second main body portion 52, the first connecting section 41 and the second connecting section 42 can extend beyond the second main body portion 52. That is, along the thickness direction of the second main body portion 52, the second main body portion 52 may not be provided on a part of the area between the first connecting section 41 and the second connecting section 42. This design can facilitate the arrangement of the transition section 43 and reduce the possibility of interference between the connecting member 4 and the first mounting bracket 5, which better meets the actual use requirements.

As shown in FIG. 7, in one or more embodiments, the high-voltage box 20 includes an arc-extinguisher 8 and a second insulating member 9. The arc-extinguisher 8 is located at the input end of the circuit breaker 3, and the second insulating member 9 is located at the output end of the circuit breaker 3. The connecting members 4 include a first connecting member 44 and a second connecting member 45, and the electronic components 2 include a fuse 21 and a relay 22. One end of the first connecting member 44 is electrically connected to the positive terminal of the output end of the circuit breaker 3, and the other end is electrically connected to the fuse 21. One end of the second connecting member 45 is electrically connected to the negative terminal of the output end of the circuit breaker 3, and the other end is electrically connected to the relay 22.

The arc-extinguisher 8 is used to realize the arc contact with a solid to reduce the arc temperature, so as to accelerate the arc extinction, thereby improving safety, and prolonging the service life of the high-voltage box 20. The second insulating member 9 is located between the first connecting member 44 and the second connecting member 45 to achieve insulation therebetween, reducing the possibility of short-circuit due to the electrical connection between the first connecting member 44 and the second connecting member 45, thereby enhancing the safety and stability of the high-voltage box 20.

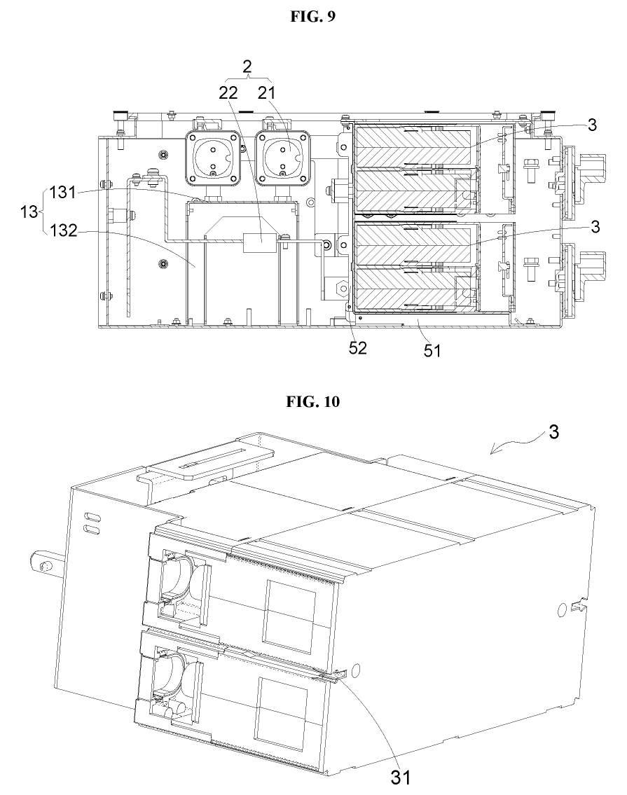

As shown in FIG. 9, in one or more embodiments, the high-voltage box 20 includes a second mounting bracket 13. The second mounting bracket 13 is located in the mounting cavity. The second mounting bracket 13 includes a mounting portion 131 and a supporting portion 132. The supporting portion 132 is connected to the mounting portion 131. The mounting portion 131 is used to install the electronic components 2, and the supporting portion 132 is connected to the box body 1. Along the thickness direction of the high-voltage box 20, there is a gap between the mounting portion 131 and the bottom wall of the accommodating cavity 11. One of the fuse 21 and the relay 22 is located on the side of the mounting portion 131 away from the bottom wall of the accommodating cavity 11, and the other is located on the side of the mounting portion 131 close to the bottom wall of the accommodating cavity 11.

This design allows the fuse 21 and the relay 22 to be arranged separately along the height direction of the high-voltage box 20, thus improving the utilization rate of the internal space of the high-voltage box 20. It reduces the space occupied by the electronic components 2 in the plane of the length and width directions of the high-voltage box 20, facilitating the optimization of the internal layout of the high-voltage box 20. As a result, the volume of the high-voltage box 20 can be reduced, which better meets the actual use requirements.

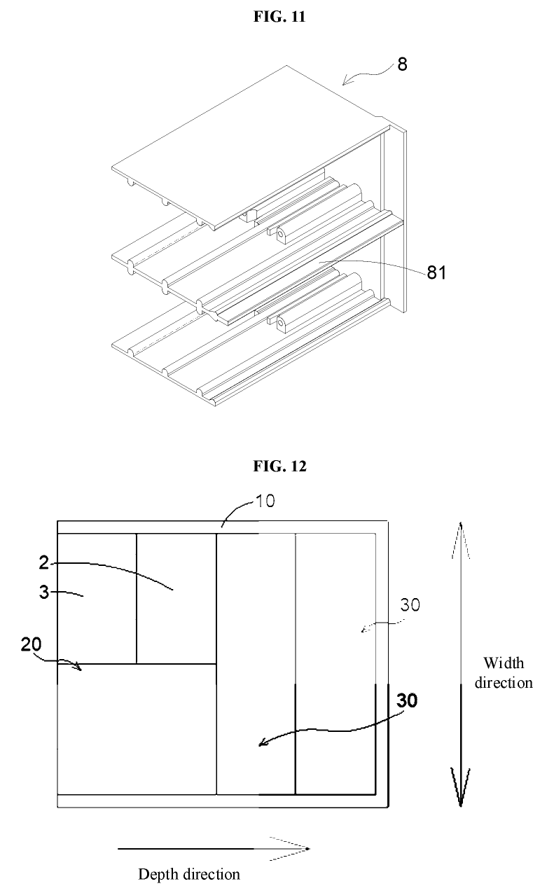

As shown in FIG. 10, in one or more embodiments, the circuit breaker 3 is provided with a mounting groove 31. As shown in FIG. 11, the arc-extinguisher 8 is provided with a third mating portion 81, and at least part of the third mating portion 81 can extend into the mounting groove 31.

During installation, the arc-extinguisher 8 can be slidably engaged with the mounting groove 31 through the third mating portion 81, and the arc-extinguisher 8 is driven to move along the mounting groove 31 to a predetermined position. This design can enhance the connection stability between the arc-extinguisher 8 and the third mating portion 81, and the operation difficulty is relatively low, which is more in line with the actual use requirements.

As shown in FIG. 6, in one or more embodiments, the high-voltage box 20 further includes a stop block 55 connected to the second main body portion 52. The stop block 55 is located on the side of the arc-extinguisher 8 away from the circuit breaker, and is used to limit the movement of the arc-extinguisher 8 relative to the circuit breaker 3. Along the installation direction of the arc-extinguisher 8, the stop block 55 can be located on the side of the arc-extinguisher 8 away from the circuit breaker 3, and the stop block 55 can abut against the arc-extinguisher 8 to limit the movement of the arc-extinguisher 8 in the direction opposite to the installation direction, thus preventing the arc-extinguisher 8 from detaching from the circuit breaker 3.

By providing the stop block 55, the arc-extinguisher 8 can be limited, thereby enhancing the installation stability of the arc-extinguisher 8 and reducing the possibility of the arc-extinguisher 8 detaching from the circuit breaker 3. This is beneficial for improving the safety and stability of the high-voltage box 20 and better meets the actual use requirements.

In one or more embodiments, the stop block 55 can be connected to the side of the second main body portion 52 away from the circuit breaker 3. The stop block 55 can be provided with an avoidance depression for structures such as the connecting member 4, reducing the possibility of interference between the stop block 55 and other internal structures of the high-voltage box 20.

As shown in FIG. 2 and FIG. 7, in one or more embodiments, the circuit breaker 3 includes a connecting rod 32. The high-voltage box 20 is provided with a connecting hole and a control member 14. The control member 14 is located outside the box body 1, and at least part of the connecting rod 32 can pass through the connecting hole and be connected to the control member 14.

This design enables the control of the circuit breaker 3 through the control member 14, which is more in line with the actual use requirements.

As shown in FIG. 2, in one or more embodiments, the high-voltage box 20 further includes a connector 15. The connector 15 is located outside the box body 1, and the input end of the circuit breaker 3 is connected to the connector 15.

The connector 15 can be used for electrical connection with the battery compartment.

When assembling the high-voltage box 20 provided by embodiments of the present disclosure, the first insulating member 7 can be first provided on the first mounting bracket 5, and the circuit breaker 3 is fixedly connected to the first mounting bracket 5. The first insulating member 7 can be arranged along the circumference of the circuit breaker 3 to protect the circuit breaker 3. Connecting members 4 such as copper bars are installed at the inlet and output ends of the circuit breaker 3 accordingly. After the at least two circuit breakers 3 are installed to the first mounting bracket 5 as required, the first mounting bracket 5, the circuit breakers 3, and the connecting members 4 are installed together within the box body 1.

This design can modularize the circuit breakers 3, the connecting members 4, and the first mounting bracket 5. Performing modular installation outside the high-voltage box 20 can reduce the space requirements for the box body 1, as well as the requirements for the operating space. Therefore, the volume of the high-voltage box 20 can be reduced. In addition, the installation operation outside the box provides a relatively large operating space, which can reduce the operation difficulty. The assembly is more convenient and faster, thus improving the assembly efficiency of the high-voltage box 20, which better meets the actual use requirements.

Based on the high-voltage box 20 provided by the above-mentioned embodiments, embodiments of the present disclosure also provide an energy storage system. The energy storage system includes an energy storage cabinet 10, a high-voltage box 20, and at least two power conversion systems 30. The high-voltage box 20 and the power conversion systems 30 are located within the energy storage cabinet 10. The energy storage cabinet 10 can be in the structure of a container, etc. The power conversion system 30 is electrically connected to the input end of the circuit breaker 3 of the high-voltage box 20. The high-voltage box 20 can be the high-voltage box 20 involved in any of the above-mentioned embodiments. Since the high-voltage box 20 has the above-mentioned technical effects, the energy storage system including this high-voltage box 20 also has corresponding technical effects, which will not be elaborated herein.

As shown in FIG. 12, the embodiments of the present disclosure provide an energy storage cabinet 10. The high-voltage box 20 and the power conversion system 30 are installed in the cavity of the energy storage cabinet 10, and the power conversion system 30 is located on one side of the high-voltage box 20. In one or more embodiments, the high-voltage box 20 is located on the side of the power conversion system 30 close to the door of the energy storage cabinet 10. That is, the installation position of the high-voltage box 20 is arranged further outward compared to the power conversion system 30. At least two power conversion systems 30 are located on the side of the high-voltage box 20 away from the door and are arranged in sequence. The electronic components 2 are provided on the side of the high-voltage box 20 close to the power conversion system 30. This design can facilitate the electrical connection between the electronic components 2 and the power conversion system 30, and reduce the wiring distance of electrical connection structures such as copper bars inside the high-voltage box 20. Thus, the internal structure of the high-voltage box 20 can be optimized, which is beneficial for reducing the volume of the high-voltage box 20. Due to the limited width of the energy storage cabinet 10, the power conversion system 30 needs to be arranged on one side of the high-voltage box 20 along the depth direction of the cavity, that is, the power conversion system 30 is located on the side of the high-voltage box 20 away from the door, which can save the space of the energy storage cabinet 10 in the width direction and is beneficial for reducing the size of the energy storage cabinet 10.

As shown in FIG. 12, along the width direction of the energy storage cabinet 10, the circuit breaker 3 and the electronic components 2 are located on the same side of the high-voltage box 20, and the other side can be used to install components such as alternating current output copper bars, pre-charge resistors, and cooling fans. The direct current input is electrically connected to the input end of the circuit breaker 3 through the connector 15. The positive terminal of the output end of the circuit breaker 3 is electrically connected to the fuse 21, the output end of the fuse 21 is electrically connected to the relay 22, the negative terminal of the output end of the circuit breaker 3 is electrically connected to the relay 22, and the output end of the relay 22 is electrically connected to the power conversion system 30. The positive terminal of the output end of the circuit breaker 3, after passing through the fuse 21, and the negative terminal of the output end are electrically connected to the same relay. Taking the case where the high-voltage box 20 includes two circuit breakers 3 as an example, the high-voltage box 20 also includes two fuses 21 and two relays 22. The positive terminal of the output end of the first circuit breaker is electrically connected to the first fuse, the output end of the first fuse is electrically connected to the first relay, and the negative terminal of the output end of the first circuit breaker is electrically connected to the first relay. The positive terminal of the output end of the second circuit breaker is electrically connected to the second fuse, the output end of the second fuse is electrically connected to the second relay, and the negative terminal of the output end of the second circuit breaker is electrically connected to the second relay. The output ends of the relays respectively lead out positive and negative outputs. That is, the side of the high-voltage box 20 close to the power conversion system 30 has four connection ends 201 for electrical connection with the power conversion system 30.

Embodiments of the present disclosure provide an energy storage system. The energy storage system includes an energy storage cabinet 10, a high-voltage box 20, and at least two power conversion systems 30. The high-voltage box 20 and the power conversion systems 30 are located in the energy storage cabinet 10, and the power conversion system 30 is electrically connected to the high-voltage box 20. The high-voltage box 20 includes a box body 1 with an accommodating cavity 11, at least two circuit breakers 3 electrically connected to electronic components 2 through connecting members 4, and a first mounting bracket 5 for installing the circuit breakers 3. The first mounting bracket 5 includes a first main body portion 51 and a second main body portion 52 that are connected to each other. The first main body portion 51 is detachably installed within the accommodating cavity 11. Along the height direction of the high-voltage box 20, each circuit breaker 3 is sequentially installed to the second main body portion 52. The circuit breakers 3 can be installed to or removed from the high-voltage box 20 together with the first mounting bracket 5. The electronic components 2 are located on the side of the second main body portion 52 away from the circuit breakers 3. The high-voltage box 20 further includes at least one support member 6. One end of the support member 6 is connected to the connecting member 4, and the other end is connected to the first mounting bracket 5. Such a design is beneficial for reducing the volume of the high-voltage box 20, lowering the assembly difficulty, and thus improving the production efficiency.

The above are only the preferred embodiments of the present disclosure and are not intended to limit the present disclosure. For those skilled in the art, the present disclosure can have various modifications and changes. The scope of the present disclosure shall be defined by the appended claims.

What is claimed is:

1. An energy storage system, comprising an energy storage cabinet, a high-voltage box, and at least two power conversion systems, the high-voltage box and the at least two power conversion systems are located within the energy storage cabinet, and the at least two power conversion systems are electrically connected to the high-voltage box,
the high-voltage box comprises:
a box body provided with an accommodating cavity;
electronic components located within the accommodating cavity;
at least two circuit breakers electrically connected to the electronic components through connecting members; and
a first mounting bracket configured to install the at least two circuit breakers to the box body.

2. The energy storage system according to claim 1, wherein the first mounting bracket comprises a first main body portion and a second main body portion that are connected to each other, the first main body portion is detachably installed within the accommodating cavity, along a height direction of the high-voltage box, each of the at least two circuit breakers is sequentially installed to the second main body portion, the at least two circuit breakers are capable of being installed to or removed from the high-voltage box together with the first mounting bracket, and the electronic components are located on a side of the second main body portion away from the circuit breakers; and
the high-voltage box further comprises at least one support member, the at least one support member each have one end connected to one of the connecting members and the other end connected to the first mounting bracket.

3. The energy storage system according to claim 2, wherein the box body includes a snap-fit portion, and the first mounting bracket includes a first mating portion;
the snap-fit portion is arranged on a bottom wall of the accommodating cavity and protrudes in a direction away from the bottom wall, an included angle between the snap-fit portion and the bottom wall is an acute angle, the snap-fit portion and the bottom wall jointly form a snap-fit space, and at least part of the first mating portion is extendable into the snap-fit space; and
the first mating portion includes at least one mating groove, when the snap-fit portion cooperates with the first mating portion, at least part of the snap-fit portion is located within the mating groove, and cooperation between the snap-fit portion and the first mating portion is configured to limit relative position of the first mounting bracket and the box body.

4. The energy storage system according to claim 3, wherein the first main body portion includes at least one second mating portion, the second mating portion is connected to the high-voltage box through mounting members, and along a length direction of the first main body portion, the first mating portion and the second mating portion are located at opposite ends of the first main body portion.

5. The energy storage system according to claim 2, wherein the at least one support member is connected to a side of the second main body portion away from the at least two circuit breakers (3); or
the first mounting bracket includes a flanging, an included angle is formed between the flanging and the first main body portion and/or the second main body portion, and the at least one support member is connected to the flanging.

6. The energy storage system according to claim 2, wherein the first mounting bracket further comprises a third main body portion, the third main body portion is located on a side of the second main body portion away from the first main body portion, one end of the third main body portion is connected to the second main body portion, and the other end of the third main body portion is connected to the box body.

7. The energy storage system according to claim 1, wherein the high-voltage box further comprises a first insulating member, the first insulating member comprises a first body part, a second body part, and a third body part, the first body part and the third body part are located at opposite sides of the second body part and each form an included angle with the second body part, the first body part, the second body part, and the third body part enclose to form an accommodating space, and the at least two circuit breakers are located in the accommodating space.

8. The energy storage system according to claim 1, wherein each of the connecting members comprises a first connecting section, a second connecting section, and at least one transition section, the first connecting section and the second connecting section are connected through the transition section, an included angle is formed between the transition section and the first connecting section and/or the second connecting section, the first connecting section is electrically connected to the circuit breaker, the second connecting section is electrically connected to the electronic components; and
the connecting members is capable of being installed to or removed from the high-voltage box together with the at least two circuit breakers.

9. The energy storage system according to claim 1, wherein the high-voltage box comprises an arc-extinguisher and a second insulating member, the arc-extinguisher is located at an input end of the circuit breaker, and the second insulating member is located at an output end of the circuit breaker;
the connecting members comprises a first connecting member and a second connecting member, the electronic components comprise a fuse and a relay, one end of the first connecting member is electrically connected to a positive terminal of the output end of the circuit breaker, and the other end of the first connecting member is electrically connected to the fuse, one end of the second connecting member is electrically connected to a negative terminal of the output end of the circuit breaker, and the other end of the second connecting member is electrically connected to the relay; and
at least part of the second insulating member is located between the first connecting member and the second connecting member.

10. The energy storage system according to claim 9, wherein the high-voltage box comprises a second mounting bracket, the second mounting bracket is located within the accommodating cavity, the second mounting bracket comprises a mounting portion and a supporting portion, a gap is provided between the supporting portion and a bottom wall of the accommodating cavity, and the supporting portion is connected to the box body; and
one of the fuse and the relay is located on a side of the mounting portion away from the bottom wall of the accommodating cavity, and the other one of the fuse and the relay is located on a side of the mounting portion close to the bottom wall of the accommodating cavity.

11. The energy storage system according to claim 9, wherein the circuit breaker includes a mounting groove, the arc-extinguisher includes a third mating portion, and at least part of the third mating portion is extendable into the mounting groove; and
the high-voltage box further comprises a stop block, the stop block is connected to the second main body portion, the stop block is located on a side of the arc-extinguisher away from the circuit breaker and is configured to limit movement of the arc-extinguisher relative to the circuit breaker.

12. The energy storage system according to claim 11, wherein the stop block is connected to a side of the second main body portion away from the circuit breaker, and the stop is provided with an avoidance depression.

13. The energy storage system according to claim 2, wherein the first main body portion includes a through-hole, the through-hole penetrates through the first main body portion along a thickness direction of the high-voltage box for cables to pass through.

14. The energy storage system according to claim 2, wherein the second main body portion includes a first mounting hole, the circuit breaker is connected to the first mounting bracket through the first mounting hole.

15. The energy storage system according to claim 5, wherein the second main body portion includes a second mounting hole at a side away from the circuit breaker for mounting the support member, and/or
the flanging includes a third mounting hole for mounting the support member.

16. The energy storage system according to claim 7, wherein the first insulating member includes an avoidance groove, the avoidance groove is configured to provide room for connection position between the circuit breaker and the first mounting bracket.

17. The energy storage system according to claim 16, wherein the avoidance groove is provided on the second body part, along a thickness direction of the high-voltage box, the first body part and the third body part are located on opposite sides of the circuit breaker, and the second body part is located on a side of the circuit breaker facing the second main body portion.

18. The energy storage system according to claim 8, wherein at least part of the first connecting section is located on a side of the second main body portion close to the circuit breaker, and at least part of the second connecting section is located on a side of the second main body portion away from the circuit breaker.

19. The energy storage system according to claim 1, wherein the circuit breaker further includes a connecting rod, the high-voltage box is provided with a connecting hole and a control member, the control member is located outside the box body, and at least part of the connecting rod passes through the connecting hole and is connected to the control member.

20. The energy storage system according to claim 1, wherein the high-voltage box further includes a connector located outside the box body, and an input end of the circuit breaker is connected to the connector.
